(19) United States
(12) Patent Application Publication
(10) Pub. No.: US 2024/0304503 A1
(43) Pub. Date: Sep. 12, 2024

(54) SPLIT PAD WITH TEST LINE

(71) Applicant: QUALCOMM Incorporated, San Diego, CA (US)

(72) Inventors: Aniket PATIL, San Diego, CA (US); Hong Bok WE, San Diego, CA (US); Brigham NAVAJA, San Diego, CA (US)

(21) Appl. No.: 18/179,223

(22) Filed: Mar. 6, 2023

(51) Int. Cl. H01L 21/66; H01L 21/48; H01L 23/498; H05K 1/02; H05K 1/11; H05K 3/40

(52) U.S. Cl. CPC H01L 22/32; H01L 21/4857; H01L 21/486; H01L 23/49816; H01L 23/49822; H01L 23/49838; H05K 1/0268; H05K 1/113; H05K 3/4038; H05K 2201/0969

(57) ABSTRACT

Disclosed are apparatuses and techniques for fabricating the apparatuses. In an aspect, an apparatus includes an outer connection layer. The outer connection layer has an outer substrate and an outer metallization layer (ML). The outer ML includes a first set of sense split pads. The first set of sense split pads includes a first pad portion and a second pad portion and a test line. The test line is coupled to the first pad portion. The first pad portion and the second pad portion are electrically coupled to a same interconnect.

### BACKGROUND OF THE DISCLOSURE

### 1. Field of the Disclosure

Aspects of the disclosure relate generally to device packaging, and in particular, to split pad designs including test lines for package routing and electrical performance improvement.

### 2. Description of the Related Art

Interconnect features and design rules, such as line/space (L/S) and via size requirements, are getting tighter as package sizes are reduced. While helpful in decreasing the overall sizes of packages, the decreasing feature sizes come with their own issues. For example, a ball grid array (BGA) for a package can have a 0.35 millimeter (mm) pitch with 220 micrometer (μm) BGA pad, which are considerably large features compared to 10/10 μm L/S and 65 μm via pad. This means that each BGA pad itself can occupy more space on the final connection layer, which leaves less space to route traces and vias on this layer. This puts significant restrictions on the final connection layer for routing. Additionally, loss of usable pads due to testing may further impact the complexity of the design layout and BGA pad configuration.

Accordingly, there is a need for systems, apparatuses and methods that overcome the deficiencies of conventional pad designs including the methods, systems and apparatuses provided herein in the following disclosure.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In accordance with the various aspects disclosed herein, at least one aspect includes, an apparatus comprising an outer connection layer comprising: an outer substrate; and an outer metallization layer (ML), the outer ML includes a first set of sense split pads comprising: a first pad portion and a second pad portion; and a test line, wherein the test line is coupled to the first pad portion, and wherein the first pad portion and the second pad portion are electrically coupled to a same interconnect.

In accordance with the various aspects disclosed herein, at least one aspect includes, a method for fabricating an apparatus comprising: forming an outer connection layer, wherein forming the outer connection layer comprises: forming an outer substrate; and forming an outer metallization layer (ML), wherein forming the outer ML comprises forming a first set of sense split pads, comprising: forming a first pad portion and a second pad portion; and forming a test line coupled to the first pad portion, and electrically coupling the first pad portion and the second pad portion to a same interconnect.

Other features and advantages associated with the apparatus and methods disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a top view of a final connection layer of a conventional package board.

FIGS. 2A-2D illustrate top views of outer connection layers of example package boards.

FIGS. 3A-3C illustrate cross-sectional views of example package boards.

FIGS. 4A-4B illustrate a physical structure of a conventional package board.

FIGS. 5A-5B illustrate a physical structure of an example package board.

FIGS. 6A-6E illustrate examples of split pad patterns.

FIG. 7 illustrates an example package.

FIG. 8A-8F illustrate stages of an example process to fabricate a package.

FIGS. 9A-9B illustrate stages of an example process to electrically couple an interconnect with split pads.

FIG. 10 illustrates a flow chart of an example method for fabricating a package.

FIG. 11 illustrates a flow chart of an example process for forming an inner connection layer.

FIG. 12 illustrates a flow chart of an example process for forming an outer connection layer and interconnects.

FIG. 13 illustrates a flow chart of an example process for forming an outer connection layer and interconnects.

FIG. 14 illustrates examples of devices with packages integrated therein.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

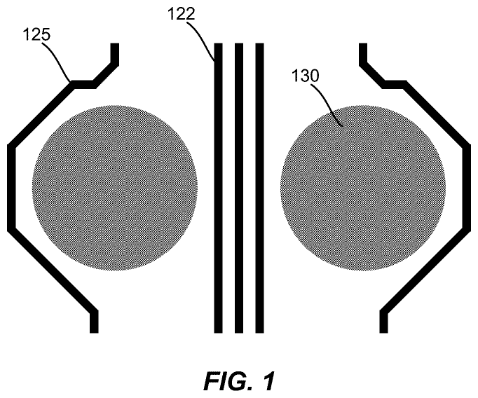

As noted above, in conventional panel level packaging, the BGA pad itself can occupy more space on the final connection layer. This leaves less space to route traces and vias, and thus puts significant restrictions on the final connection layer for routing. FIG. 1 illustrates a top view of a final connection layer, which is the outermost connection layer, of a conventional package board, such as a printed circuit board (PCB). This outer connection layer includes pads 130 which serve as contact pads for solder balls. The outer connection layer also includes traces 122 and bent traces 125 to carry power, ground, and data signals.

The bent traces 125 are bent due to the presence of the pads 130. There are several disadvantages. As indicated above, one disadvantage is that the pad 130 can have considerably large features leaving less space to route the traces 122, 125 and vias (not shown), i.e., there can be a major restriction for routing. Another disadvantage is the bent traces 125 have increased length, which correspondingly increases signal propagation delay. Further, due to the large size of the pads 130, there can be an increase in the coupling effect.

To address one or more issues associated with the conventional package board, it is proposed to split the pad into two or more sub-pads to allow for more efficient routing on at least the final-i.e., the outermost-connection layer of a package board. It should be noted that while terms such as “upper”, “lower”, “left”, “right”, “top”, “bottom”, etc. are used in this disclosure, they should not be taken as defining absolute orientations. Rather, they should be taken simply as terms of convenience to indicate relative locations and orientations of the described components.

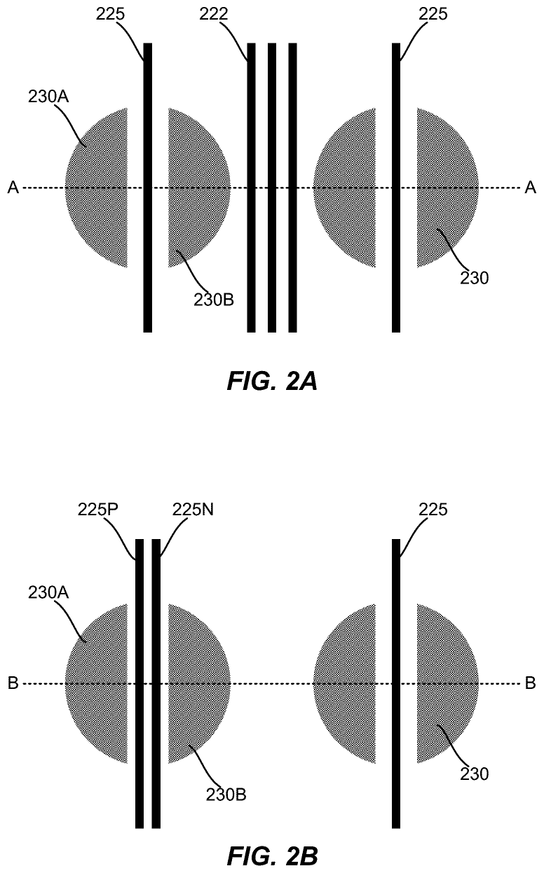

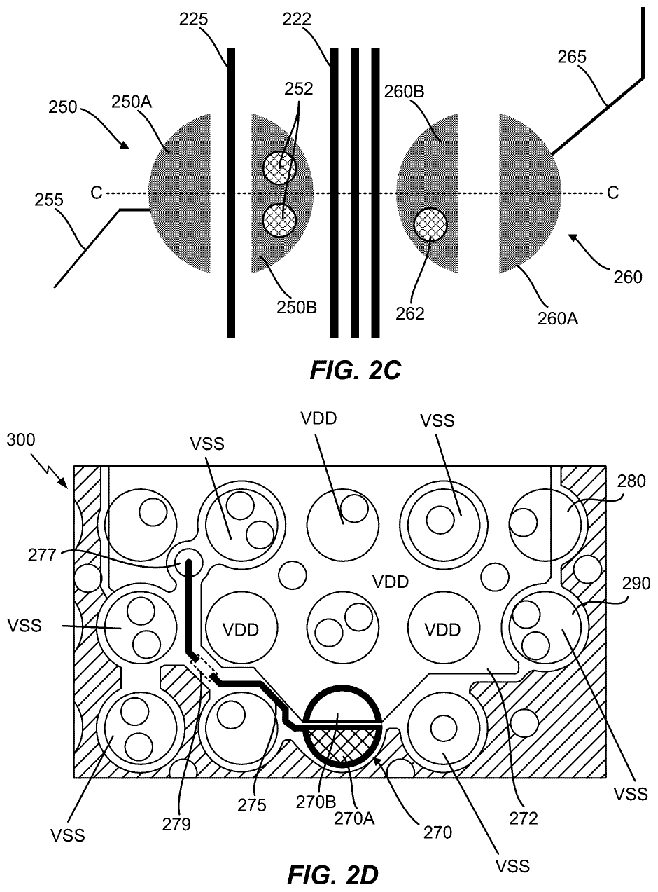

FIG. 2A illustrates a top view of a final connection layer of an example package board. A package substrate, printed circuit board (PCB), and/or circuit card assembly (CCA) may be an example of a package board. The final connection layer is the outermost layer of the package board. For convenience, the final connection layer will also be referred to as the “outer connection layer”. The outer connection layer may include any number of split pads 230, traces 222, and through-traces 225. It will be appreciated that commercial devices may have hundreds or more pads, but to minimize clutter, not all of the split pads 230, the traces 222, and the through-traces 225 of a given design are illustrated or labeled in FIG. 2A. The split pads 230, the traces 222, and the through-traces 225 may be viewed as being parts of an outer metallizations layer (ML), which may also be referred to as a redistribution layer (RDL), series of routing traces, etc., of the outer connection layer. The outer metallization layer (ML) is also referred to as “outer ML” for convenience. The outer ML includes the split pads 230, the traces 222, and the through-traces 225, which in some aspects may be formed from conductive materials such as copper.

The split pads 230 may serve as contact pads for interconnects (e.g., solder balls) for external connection. In this way, the package board 300 may connect with other package boards and devices external to the package board. The traces 222 and the through-traces 225 may be configured to carry power, ground, and data signals. The outer connection layer may also include an outer substrate (not shown in FIG. 2A).

As will be shown further below, two or more (i.e., multiple) split pads 230 may be electrically coupled to each other. To state it another way, each split pad 230 may be electrically coupled to at least one other split pad 230. For illustration purposes, two of the split pads 230 are labeled in FIG. 2A as first and second split pad 230A, 230B. The first and second split pads 230A, 230B may be electrically coupled to each other.

One significant difference (not necessarily the only difference) between the proposed outer connection layer of FIG. 2A and the conventional final connection layer of FIG. 1 is that the outer connection layer of FIG. 2A includes the through-traces 225, which are traces that are laterally disposed between electrically coupled split pads 230. As seen in FIG. 2A, at least one through-trace 225 may be laterally in between the first and second split pads 230A, 230B. Also, as will be shown further below, the at least one through-trace 225 may be electrically separate from the first and second split pads 230A, 230B. Unlike the bent traces 125 of the conventional final connection layer, the spacing between the first and second split pads 230A allows the through-trace 225, or at least the portion of the through-trace 225 in between the first and second split pads 230A, to be straight.

FIG. 2B illustrates a top view of another example package board. The difference between FIGS. 2A and 2B is that in FIG. 2B, there are two through-traces 225 (respectively referred to as first and second through-traces 225P, 225N) in between the first and second split pads 230A, 230B. This is simply to illustrate that there can be any number of through-traces 225 that may be in between any two electrically coupled split pads 230. While not specifically illustrated, it is contemplated that the outer connection layers of one or both of FIGS. 2A, 2B may also include bent traces 125.

FIG. 2C illustrates a top view of another example package board or another portion of one of the previous package boards (e.g., package board 300). The outer connection layer may include any number of sets of sense split pads 250 and 260, traces 222, and through-traces 225. The set of sense split pads 250 and 260, the traces 222, the through-traces 225 and test line 255 and test line 265 may be viewed as being parts of the metallizations layer (ML). As used herein, the term “set of sense split pads” refers to split pads (or pad portions of the set) that are associated with a pad portion that is connected to a test line and electrically coupled to a common interconnect (e.g., solder ball, etc.). It will be appreciated that the fabrication and materials of the various split pads discussed herein apply to the set of sense split pads and the individual pad portions discussed herein. The set of sense split pads 250 and 260 may serve as contact pads for interconnects for external connection. In this way, the package board 300 may connect with other package boards and devices external to the package board. As noted above, the traces 222 and the through-traces 225 may be configured to carry power, ground, and data signals. The outer connection layer may also include an outer substrate (not shown in FIG. 2C).

In the aspect illustrated in FIG. 2C, the outer ML includes a first set of split pads 250. The first set of split pads 250 includes a first pad portion 250A and a second pad portion 250B one or more through-traces 225 (optional) and a test line 255. The test line 255 is coupled to the first pad portion 250A. The first pad portion 250A and the second pad portion 250B are electrically coupled to a same interconnect (not illustrated in FIG. 2C). The second pad portion 250B is electrically coupled to a power distribution network (PDN) through one or more PDN connections 252 at either a positive or negative/ground potential (e.g., either VDD or VSS). In some aspects, the at least one through-trace 225 of the one or more through-traces vertically overlaps the same interconnect and is laterally disposed between the first pad portion 250A and the second pad portion 250B of the first set of split pads 250.

Likewise, a second set of split pads 260 includes a first pad portion 260A and a second pad portion 260B and a test line 265 (as illustrated, in some aspects the split pads may not have through-traces). The test line 265 is coupled to the first pad portion 260A. The first pad portion 260A and the second pad portion 260B are electrically coupled to a same interconnect (not illustrated in FIG. 2C). The second pad portion 260B is electrically coupled to the PDN through PDN connection 262. It will be appreciated that the PDN connections (e.g., 252, 262) may be one or more vias, traces, shapes or planes.

In an aspect illustrated in FIG. 2D, the outer ML includes a first set of sense split pads 270, which may be similar to sense split pads 250 and 260, discussed above. Sense split pads 270 includes a first pad portion 270A and a second pad portion 270B and a test line 275. The test line 275 is coupled to the first pad portion 270A and to a test point 277 in the outer ML. The first pad portion 270A and the second pad portion 270B are electrically coupled to a same interconnect (e.g., a solder ball over both pads, not illustrated in FIG. 2D). The second pad portion 270B is electrically coupled to the PDN through PDN connection 272, which in the illustrated example is a VDD plane which is coupled to other VDD pads 280, which are not split pads. Likewise, the VSS pads 290 of the PDN are not split pads in this portion of the package board 300. The test line 275 is a very fine trace used for test purposes. Accordingly, in some aspects, the test line has a width that is 20 μm or less. For example, the test line 275 can have a trace width configured to the minimum size per system design rules, such as, 20 μm, 15 μm, or less. In contrast, the core PDN routing is designed opposite. The PDN traces and shapes are greater than 20 um. The core PDN traces, features, etc. are as wide as possible given the spacing limitations and are designed for thicker/wider traces. In some aspects, the test line 275 may have an opened portion 279 in the final product so that the second pad portion 270B is disconnected from the test point 277. For example, after testing is completed, a high current/high voltage may be applied to open the test line 275.

In the aspect illustrated in FIG. 2C and FIG. 2D, it will be appreciated that the test line can be used for testing purposes during the manufacturing process. Afterwards, the test lines become non-connected in the commercial product. In some examples, there may be on the order of three percent (3%) of the core pads use for testing (e.g., 25 or more pads used for test out of seven hundred or more available core PDN pads). The various aspects disclosed allow for a set of sense split pads where one pad (e.g., 250B, 260B, 270B) will connect to the PDN (e.g., VDD/VSS rail) and another pad (e.g., 250A, 260A, 270A) will connect to a test point (e.g., test point 277) with a separate test line (e.g., 255, 265, 275). In one advantageous aspect, this allows for pads to be used during test and then later connected to the PDN, which increases the useful pads/pins available (e.g., by the 3% previously dedicated to test in conventional designs).

The following are some (not necessarily exhaustive) of the additional advantages of the various aspects disclosed. Mechanically, the routing for a given design may be simplified as compared to the conventional final connection layer. Also, the through-traces 225 can occupy less space than the conventional bent traces 125. Further, the through-traces 225 in general can have less bends and trace length.

There are also electrical advantages. One electrical advantage is that shielding may be provided for high-speed signals. For example, in FIG. 2A, the first and second split pads 230A, 230B may be grounded and the through-trace 225 in between may carry a high-speed signal. Grounding the first and second split pads 230A, 230B can provide shielding so that the high-speed signal may be more reliably carried on the through-trace 225. In FIG. 2B, the high-speed signal may be carried by the first and second through-traces 225P, 225N as a differential signal pair. Again, grounding the first and second split pads 230A, 230B can provide shielding to the high-speed differential signal pair carried on the through-traces 225P, 225N.

Another electrical advantage is that unwanted capacitive coupling can be reduced. Note that in an aspect, the sizes of the first and second split pads 230A, 230B combined can still be smaller than the size of a single pad 130 of the conventional final connection layer. The reduced pad sizes can effectively reduce capacitive coupling that takes place.

Further, it will be appreciated that the various split pads disclosed herein may be used in combination in a given package board to provide for combinations of the various beneficial aspects discussed, such as improved routing, shielding and elimination of wasted test pads.

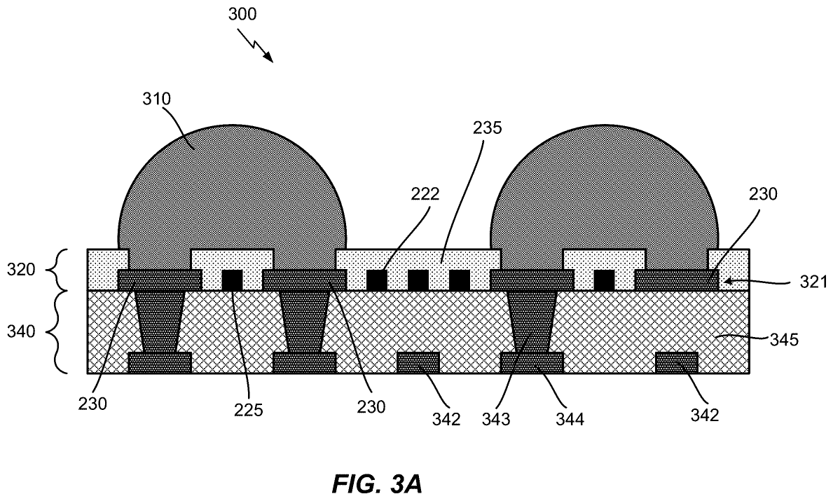

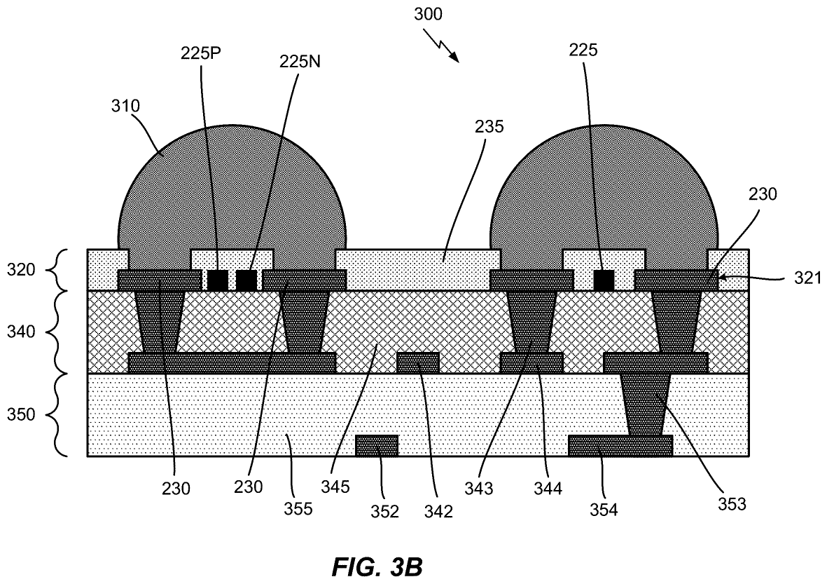

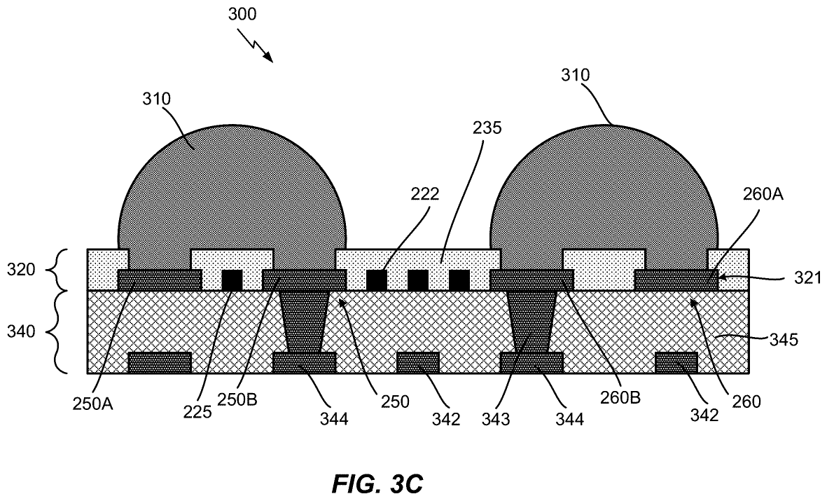

FIGS. 3A, 3B and 3C illustrate cross-sectional views of example package boards 300. FIG. 3A may represent a cross-sectional view taken along the line “A-A” in FIG. 2A, and FIG. 3B may represent a cross-sectional view taken along the line “B-B” in FIG. 2B, and FIG. 3C may represent a cross-sectional view taken along the line “C-C” in FIG. 2C. As seen, the package board 300 may include an inner connection layer 340 and an outer connection layer 320 on and above the inner connection layer 340. For example, a bottom surface of the outer connection layer 320 may be in physical contact with a top surface of the inner connection layer 340. The package board 300 may also include any number of interconnects 310 on and above the outer connection layer 320.

The outer connection layer 320 may include an outer substrate 235 and an outer ML 321 within the outer substrate 235. The outer substrate 235 may be formed from electrically insulating materials such as dielectrics. The outer ML 321 may be below a top surface of the outer connection layer 320 and on the top surface of the inner connection layer 340. For example, the outer ML 321 may directly contact the top surface of the inner connection layer 340. The outer ML 321 may include any number of the split pads 230, the through-traces 225, and the traces 222. The outer ML may be formed from conductive materials such as metal (e.g., copper, silver, gold, aluminum, tin, and the like).

Bottom surfaces of the outer substrate 235 and the outer ML may together define a bottom surface of the outer connection layer 320. That is, the bottom surfaces of the outer substrate 235, the split pads 230, the through-traces 225, and the traces 222 may define the bottom surface of the outer connection layer 320. The outer ML 321 then may be viewed as vertically extending from the bottom surface of the outer connection layer 320 to a height below the top surface of the outer connection layer 320. In an aspect, the bottom surface of the outer connection layer 320 may be planar, i.e., the bottom surface of the outer substrate 235 may be planar with the bottom surfaces of the split pads 230, the through-traces 225, and the traces 222.

As noted above with respect to FIGS. 2A and 2B, multiple (i.e., two or more) split pads 230 may be electrically coupled to each other. One way to accomplish this is to electrically couple the multiple split pads 230 to a common or a same interconnect 310. In FIGS. 3A and 3B, the left interconnect 310 is illustrated as being the same interconnect 310 electrically coupled to the left two split pads 230. Similarly, the right interconnect 310 is illustrated as being the same interconnect 310 electrically coupled to the right two split pads 230. Electrical coupling may be accomplished through physical contact. For example, the left interconnect 310 may be in physical contact with upper surfaces of the left two split pads 230. For ease of description, the left two split pads 230 may be referred to as the first and second split pads 230 in relation to the left interconnect 310. Similarly, the right two split pads 230 may be referred to as the first and second split pads 230 in relation to the right interconnect 310.

Also recall that the through-traces 225 may be laterally in between the electrically coupled split pads 230. This is also illustrated in FIGS. 3A and 3B. As seen, the left through-trace 225 may be laterally in between the left two split pads 230, and the right through-trace 225 may be laterally in between the right two split pads 230. More generically, the through-trace 225 may be laterally in between the first and second split pads 230. A consequence is that the left through-trace 225 may vertically overlap the left interconnect 310 and the right through-trace 225 may vertically overlap the right interconnect 310. More generically, the through-trace 225 may vertically overlap the same interconnect 310. Moreover, at least a portion of the through-trace 225 that vertically overlaps the same interconnect 310 may be straight (see FIGS. 2A, 2B).

The inner connection layer 340 may include an inner substrate 345 and an inner ML within the inner substrate 345. The inner substrate 345 may be formed from electrically insulating materials such as dielectrics. The inner ML may be below the top surface of the inner connection layer 340. The inner ML may include any number of inner traces 342 and any number of inner connection pads 344. The inner ML may be formed from conductive materials such as metal (e.g., copper).

Bottom surfaces of the inner substrate 345 and the inner ML may together define a bottom surface of the inner connection layer 340. That is, the bottom surfaces of the inner substrate 345, the inner traces 342, and the inner connection pads 344 may define the bottom surface of the inner connection layer 340. The inner ML then may be viewed as vertically extending from the bottom surface of the inner connection layer 340 to a height below the top surface of the inner connection layer 340. In an aspect, the bottom surface of the inner connection layer 340 may be planar, i.e., the bottom surface of the inner substrate 345 may be planar with the bottom surfaces of the inner traces 342, and the inner connection pads 344.

The inner connection layer 340 may also include any number of inner vias 343. The inner vias 343 may be formed on the inner connection pads 344 such that each inner via 343 is electrically coupled to its corresponding inner connection pad 344. For example, bottom surfaces of the inner vias 343 may be in physical contact with upper surfaces of the corresponding inner connection pads 344. The inner vias 343 may be formed from conductive materials such as metal (e.g., copper).

The inner vias 343 may also be electrically coupled to the split pads 230 of the outer connection layer 320. For example, in FIG. 3A, the three inner vias 343 are shown as being in physical contact with three of the split pads 230—to both of the first and second split pads 230 of the left interconnect 310 and to one of the first and second split pads 230 of the right interconnect 310. In FIG. 3B, the four inner vias 343 are shown as being in physical contact with all four of the split pads 230—to both of the first and second split pads 230 of the left interconnect 310 and to both of the first and second split pads 230 of the right interconnect 310.

For ease of description, the left two inner vias 343 may be referred to as first and second inner vias 343 in relation to the left interconnect 310. In this instance, it is seen that the first and second inner vias 343 are also electrically coupled to each other, e.g., at least through the left interconnect 310. If the left through-trace 225 is a high signal trace, then shielding can be provided by grounding the left interconnect 310, which in turn would ground the related first and second split pads 230, the first and second inner vias 343, and the corresponding inner connection pads 344. As seen in FIG. 3B, the first and second inner vias 343 may also be electrically coupled to each other through a common or same inner connection pad 344.

It should be noted that it is not a requirement that every split pad 230 be connected to an inner via 343. That is, each split pad 230 may or may not be physically connected to an inner via 343 intentionally based on routing preferences. For example, as seen in FIG. 3A, the right most split pad 230 is not in contact with any of the inner vias 343, i.e., for the right interconnect 310, only one of the related first and second split pads 230 is electrically coupled to its corresponding inner via 343 (e.g., through physical contact). The capability to physically connect the split pads 230 intentionally provides flexibility in routing of the inner ML. For example, an inner trace 342, which is not electrically coupled to the right most split pad 230, may be located so as to vertically overlap the right most split pad 230.

It is contemplated that there can be any number of inner connection layers. The example package board 300 of FIG. 3A includes one inner connection layer (layer 340) and the example package board 300 of FIG. 3B includes two inner connection layers (layers 340, 350). Regarding FIG. 3B, for clarity, the term “second” will be used in reference to the inner connection layer 350.

The second inner connection layer 350 may include a second inner substrate 355 and a second inner ML within the second inner substrate 355. The second inner substrate 355 may be formed from electrically insulating materials such as dielectrics. The second inner ML may include any number of second inner traces 352 and any number of second inner connection pads 354. The second inner ML may be formed from conductive materials such as metal (e.g., copper).

Bottom surfaces of the second inner substrate 355 and the second inner ML may together define a bottom surface of the second inner connection layer 350. That is, the bottom surfaces of the second inner substrate 355, the second inner traces 352, and the second inner connection pads 354 may define the bottom surface of the second inner connection layer 350. The second inner ML then may be viewed as vertically extending from the bottom surface of the second inner connection layer 350 to a height below the top surface of the second inner connection layer 350. In an aspect, the bottom surface of the second inner connection layer 350 may be planar, i.e., the bottom surface of the second inner substrate 355 may be planar with the bottom surfaces of the second inner traces 352, and the second inner connection pads 354.

The second inner connection layer 350 may also include any number of second inner vias 353. The second inner vias 353 may be formed on the second inner connection pads 354 such that each second inner via 353 is electrically coupled to its corresponding lower connection pad 354. For example, bottom surfaces of the second inner vias 353 may be in physical contact with top surfaces of the corresponding lower connection pads 354. The second inner vias 353 may be formed from conductive materials such as metal (e.g., copper).

The second inner vias 353 may also be electrically coupled to the inner connection pads 344 of the inner connection layer 340. For example, in FIG. 3B, the rightmost second inner via 353 is shown as being in physical contact with the rightmost inner connection pad 344. Again, whether or not a particular inner connection pad 344 is connected to a second inner via 353 may be intentionally made depending on the routing preferences.

FIG. 3C illustrates a cross-sectional view taken along the line “C-C” in FIG. 2C. As noted above with respect to FIGS. 2C and 2D, multiple (i.e., two or more) pad portions of a set of sense split pads 250 or 260 may be electrically coupled to each other. As noted above, this can be accomplished by electrically coupling the set of sense split pads 250 or 260 to a common or a same interconnect 310 (e.g., solder ball). In FIG. 3C, the left interconnect 310 is illustrated as being the same interconnect 310 electrically coupled to the first pad portion 250A and second pad portion 250B of the set of sense split pads 250. Similarly, the right interconnect 310 (which is being used generically for the illustrated interconnects) is illustrated as being the same interconnect 310 electrically coupled to the first pad portion 260A and second pad portion 260B of the set of sense split pads 260. Electrical coupling may be accomplished through physical contact of the interconnects 310 to the individual pad portions.

As discussed above, through-trace 225 may be laterally disposed between the electrically coupled first pad portion 250A and second pad portion 250B. This is also illustrated in FIG. 3C. Accordingly, the through-trace 225 may vertically overlap the left interconnect 310. In contrast, the electrically coupled first pad portion 260A and second pad portion 260B do not have any traces disposed between them. Additionally, in the illustrated example, traces 222 are disposed between the set of sense split pads 250 and 260. It will be appreciated that the illustrated configuration is provided merely as an example to aid in discussion of the various aspects and more or less traces and through-traces may be provided and routed in different paths. Further, as will be appreciated from the illustration, in some aspects, the various split pads of FIGS. 3A, 3B and 3C may be part of a common package board 300.

As discussed above, the inner connection layer 340 may include an inner substrate 345 and an inner ML within the inner substrate 345. The inner substrate 345 may be formed from electrically insulating materials such as dielectrics. The inner ML may be below the top surface of the inner connection layer 340. The inner ML may include any number of inner traces 342 and any number of inner connection pads 344. The inner ML may be formed from conductive materials such as metal (e.g., copper).

The inner connection layer 340 may also include any number of inner vias 343. The inner vias 343 may be formed on the inner connection pads 344 such that each inner via 343 is electrically coupled to its corresponding inner connection pad 344. For example, bottom surfaces of the inner vias 343 may be in physical contact with upper surfaces of the corresponding inner connection pads 344. The inner vias 343 may be formed from conductive materials such as metal (e.g., copper).

In some aspects, the inner vias 343 may also be electrically coupled to the second pad portion 250B and the second pad portion 260B in the outer connection layer 320. For example, in FIG. 3C, the two inner vias 343 are shown as being in physical contact with the second pad portion 250B and the second pad portion 260B. In some aspects the inner connection pads 344 may be part of a PDN and may be a VDD/VSS power rail and/or coupled to a power rail. The first pad portion 250A and the second pad portion 260A are not coupled to a via, such as inner via 343, but instead are each coupled to a test line (not visible, but as discussed above in relation to FIGS. 2C and 2D).

As discussed above, the various aspects disclosed are not limited to any specific number of inner connection layers. The example package board 300 of FIG. 3C includes one inner connection layer (layer 340) and the example package board 300 of FIG. 3B includes two inner connection layers (layers 340, 350). Further, it will be appreciated that, in some aspects, the illustration of FIG. 3C may be interpreted as a partial illustration and the second inner connection layer 350 of FIG. 3B can be applied to FIG. 3C, such that the various split pads in FIGS. 3B and 3C may be part of the same package board 300.

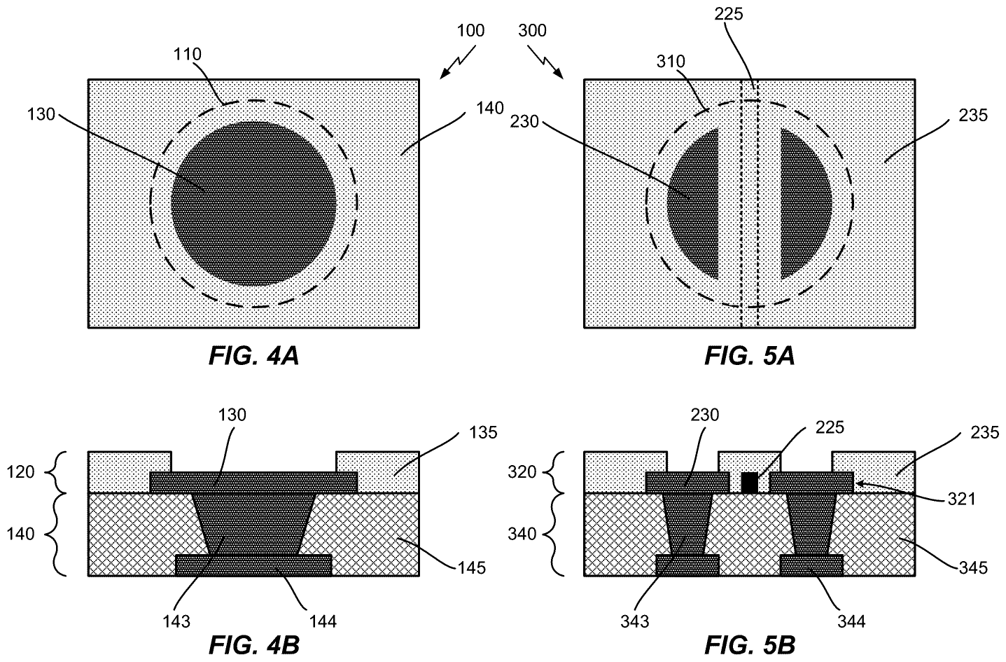

FIG. 4A-5B are provided to highlight some of the advantages of the proposed package boards relative to the conventional package boards. FIG. 4A and FIG. 4B respectively illustrate top and cross-sectional views of a conventional package board 100 and FIG. 5A and FIG. 5B illustrate top and cross-sectional views of an example package board as proposed. As seen in FIGS. 4A, 4B the conventional package board 100 includes a final connection layer 120 on an inner connection layer 140. The final connection layer 120 includes the solder pad 130 and a final substrate 135. The inner connection layer 140 includes an inner substrate 145 and an inner via 143 on an inner connection pad 144. In FIG. 4A, the dashed circle represents an outline of an area occupied by a solder ball 110.

As seen in FIGS. 5A, 5B, the example package board 300 may include the inner connection layer 340, the outer connection layer 320 on and above the inner connection layer 340, and one or more interconnects 310 on and above the outer connection layer 320. The outer connection layer 320 may include an outer substrate 235 and the outer ML 321 (split pads 230, through-traces 225, traces 222) within the outer substrate 235. The inner connection layer 340 may include the inner substrate 345, the inner ML (inner traces 342, inner connection pads 344), and inner vias 343. In FIG. 5A, the short dashed rectangle represents an outline of a through-trace 225 within the outer substrate 235.

As mentioned, routing at the outer connection layer 320 may be made simpler and more flexible due to the through-traces 225. The through-traces 225 can occupy less space than the conventional bent traces 125 and have less bends and trace length. Electrically, shielding may be provided. Also electrically, unwanted coupling effects can be minimized due to reduction in sizes of the split pads 230, the inner vias 343, and the inner connection pads 344. These aspects are also provided by the split pads with test lines, as disclosed in the foregoing.

Another electrical advantage is that unwanted coupling effect can be reduced. Note that in an aspect, the size of the first and second split pads 230A, 230B, and also pad portions 250A, 250B, combined can still be smaller than the size of a single pad 130 of the conventional final connection layer. The reduced pad sizes can effectively reduce capacitive coupling that takes place.

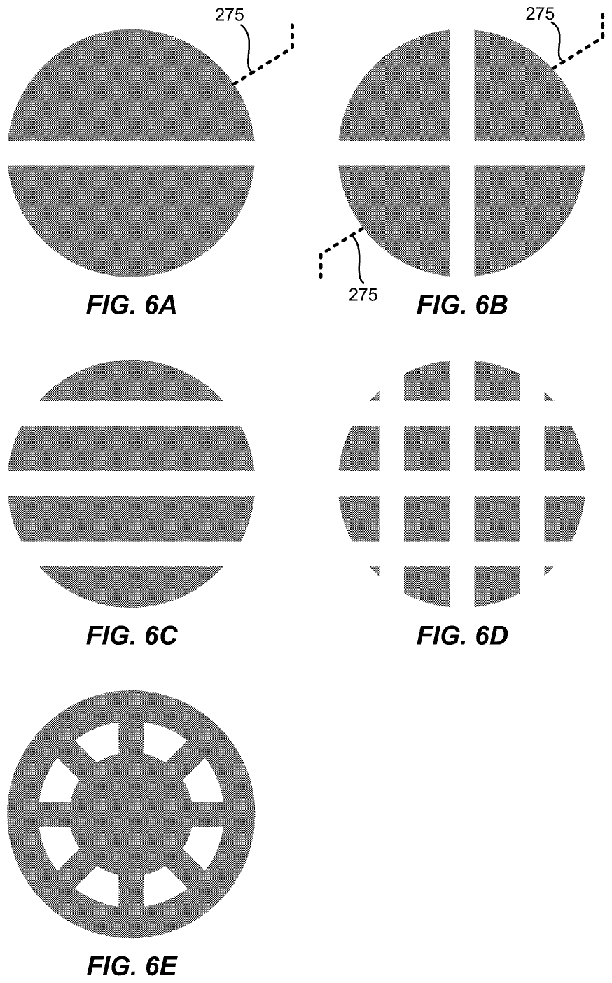

It should be noted that the split pads 230 and sense split pads 250 may take on a variety of patterns as illustrated in FIGS. 6A-6E. For drawing clarity, the individual split pads 230 are not numbered in FIGS. 6A-6E. For each of the FIGS. 6A-6E, the split pads may be electrically coupled to each other. That is, both split pads in FIG. 6A are electrically coupled, all four split pads in FIG. 6B are electrically coupled, and so on. Further, it will be appreciated that the various split pad configurations of FIGS. 6A-6D may optionally have one or more test lines 275 to the various split portions. Accordingly, in the various aspects disclosed the sense split pad may have at least one additional pad portion (e.g., three or more) and/or at least one additional test line 275 (e.g., two or more). The example optional connections of test lines 275 are provided merely for illustration and it will be appreciated that the various aspects disclosed and claimed are not limited to the illustrated examples.

While not specifically illustrated, it should be noted that any number (i.e., zero or more) through-traces 225 may be in the spacing between any two split pads. Also, the widths of the spacings need not be uniform, i.e., some spacings may be wider than others. Further, the spacings need not be limited to up/down and side/side orientations, i.e., they may be oriented in any angle. If under bump metallization (UBM) is used, then patterns like that of FIG. 6D can be used to reduce capacitance at the expense of the UBM area. Patterns like that of FIG. 6E can provide continuous UBM but with reduced metal area.

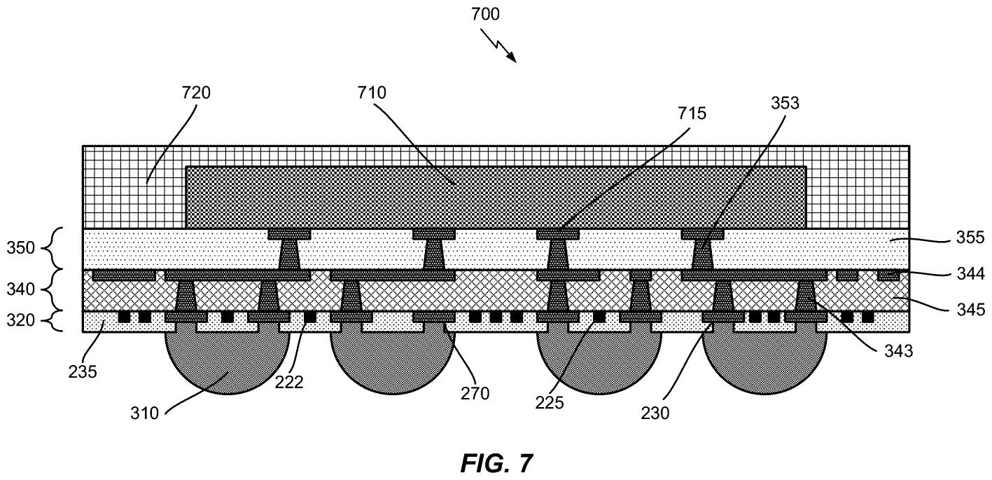

FIG. 7 illustrates an example of a package 700 that connects a die 710 to the package board 300. The package board 300 is illustrated as including the outer connection layer 320, the inner connection layer 340, and the second inner connection layer 350. While the number of inner connection layers is two in this figure, it should be noted that there can be any number of inner connection layers. As seen, the interconnects 310 may be electrically connected to die pins 715 of the die 710 through the split pads 230, the inner vias 343, the inner connection pads 344, and the second inner vias 353. Additionally, the interconnects 310 may be electrically connected to die pins 715 of the die 710 through the one or more sense split pads 270, the inner vias 343, the inner connection pads 344, and the second inner vias 353, while a portion of the sense split pad 270 may be connected to a test line for testing (as discussed in the foregoing). Further, conventional solid pads may be used in combination with the split pads 230 and sense split pads 270 to provide access to the die 710. The die 710 may be provided on an inner most connection layer (the second inner connection layer 350 in this instance). For protection, the die 710 may be encapsulated with a mold 720. The package 700 may be applicable to various types of packaging technology such as wafer level package (WLP), fan-out WLP (FOWLP), and the like.

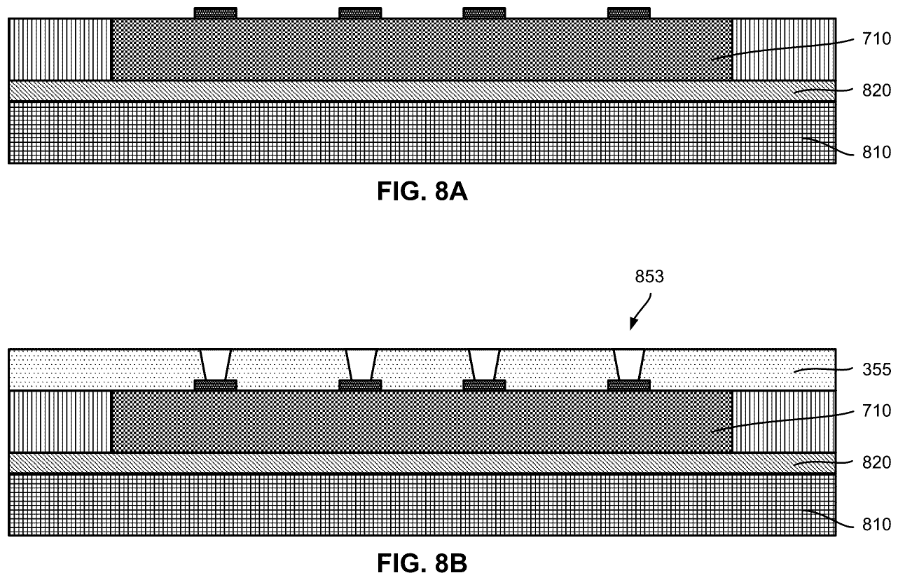

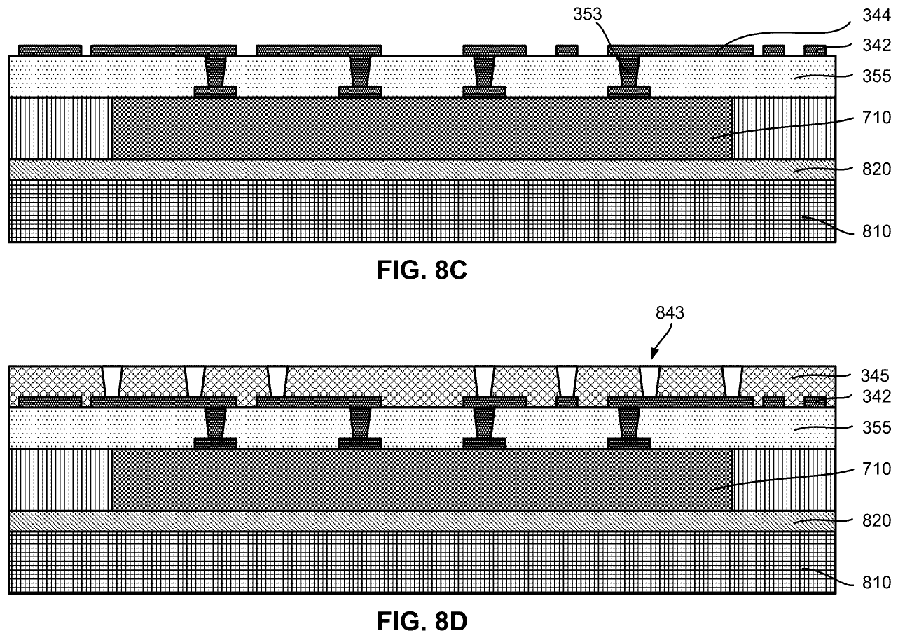

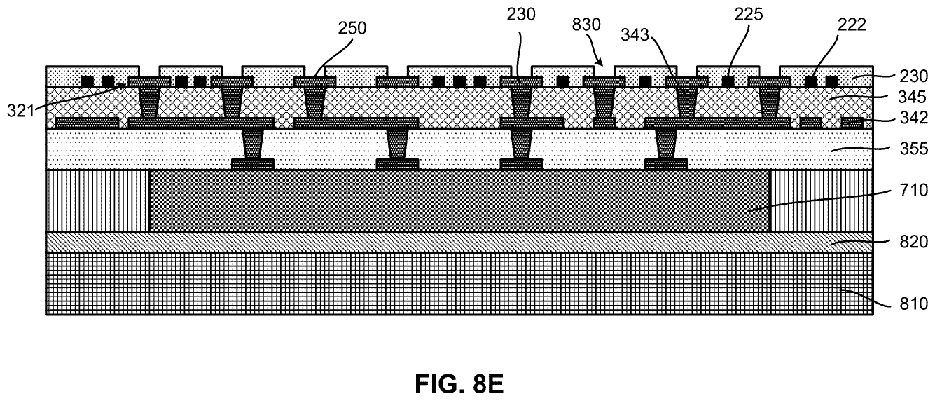

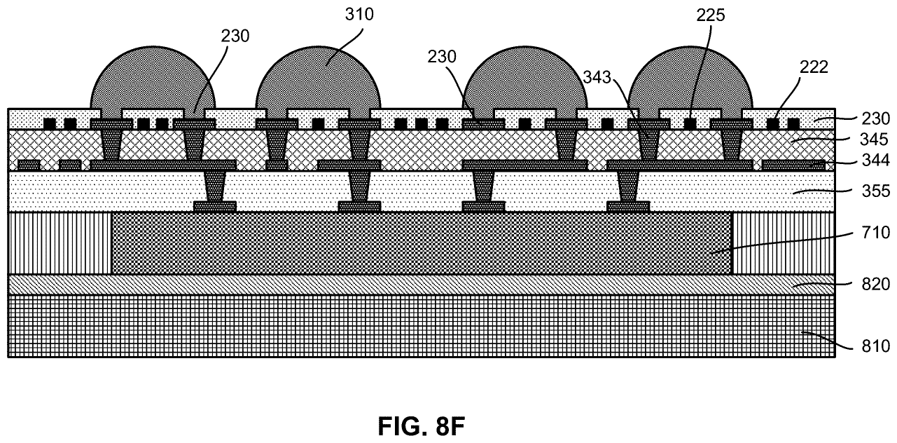

FIG. 8A-8F illustrate stages of an example process to fabricate a package such as the package 700. FIG. 8A illustrates a stage in which the die 710 may be placed on a carrier 810 on a release layer 820. FIG. 8B illustrates a stage in which a substrate, such as the second inner substrate 355, may be deposited on the die 710. The second inner substrate 355 may be etched to form second inner via holes 853 to expose the die pins 715. For example, a photoresist mask (PM) may be applied and lithography may be performed. Note that the second inner substrate 355 may also be planarized.

FIG. 8C illustrates a stage in which the conductive material such as copper may be deposited in the second inner via holes 853 to form the second inner vias 353. The conductive material may also be deposited on the upper surface of the second inner substrate 355 and etched to form the inner ML of the inner connection layer 340, i.e., to form the inner traces 343 and the inner connection pads 344. For example, masking and lithography procedures may be used. It is seen that the second inner vias 353 of the second inner connection layer 350 and the inner connection pads 344 of the inner connection layer 340 may be formed integrally.

FIG. 8D illustrates a stage in which another substrate, such as the inner substrate 345, may be deposited on the second inner connection layer 350. The inner substrate 345 may be etched to form inner via holes 843 to expose the inner connection pads 344. For example, masking and lithography procedures may be used. The inner substrate 345 may also be planarized.

FIG. 8E illustrates a stage in which the outer connection layer 320 may be formed. For example, a conductive material such as copper may be deposited in the inner via holes 843 to form the inner vias 343. The conductive material may also be deposited on the upper surface of the inner substrate 345 and etched to form the outer ML 321 of the outer connection layer 320, i.e., to form the traces 222, the through-traces 225, and the split pads 230, sense split pads (e.g., 250) and test lines (e.g., 255, not expressly illustrated). It is then seen that the inner vias 343 of the inner connection layer 340 and the split pads 230 of the outer connection layer 320 may be formed integrally. Thereafter, the outer substrate 235 may be deposited on the upper surface of the inner connection layer 340 and on the outer ML 321. Masking and lithography procedures may be used to etch the outer substrate 235 to form the split pad holes 830 to expose the split pads 230. The outer substrate 235 may also be planarized.

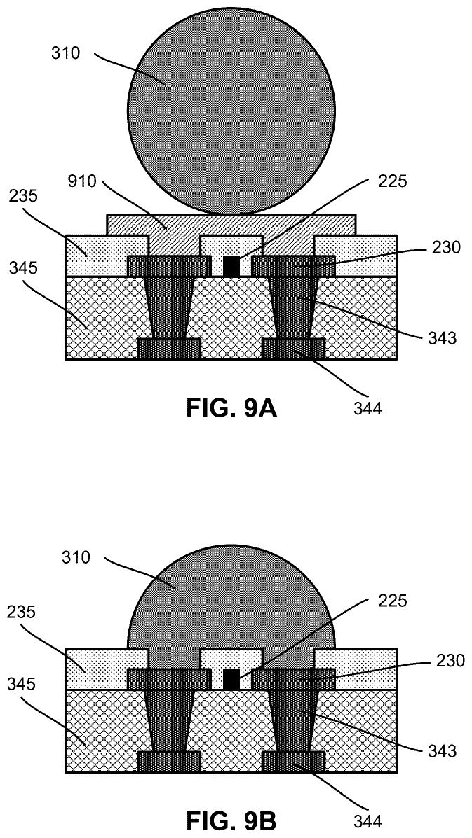

FIG. 8F illustrates a stage in which the interconnects 310 may be formed on the outer connection layer 320. In particular, the interconnects 310 may be formed to be electrically coupled to the split pads 230. FIGS. 9A, 9B illustrate stages of an example process to electrically couple an interconnect 310 with split pads 230. FIG. 9A illustrates a stage in which flux 910 is applied over the exposed split pads 230 and over the outer substrate 235, and a solder bump (not numbered) is on the flux 910. FIG. 9B illustrates a stage after a reflow is performed.

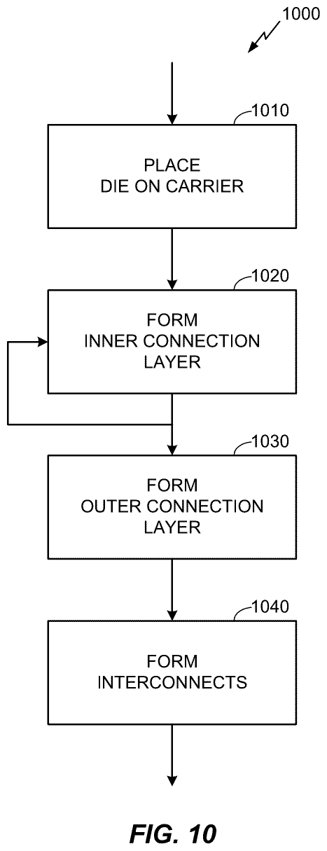

FIG. 10 illustrates a flow chart of an example method for fabricating a package such as the package 700. The method 1000 includes, in block 1010, that a die may be placed on a carrier. FIG. 8A may correspond to block 1010. In block 1020, an inner connection layer may be formed. Block 1020 may be repeated to form any number of inner connection layers such as the layers 340, 350 discussed above.

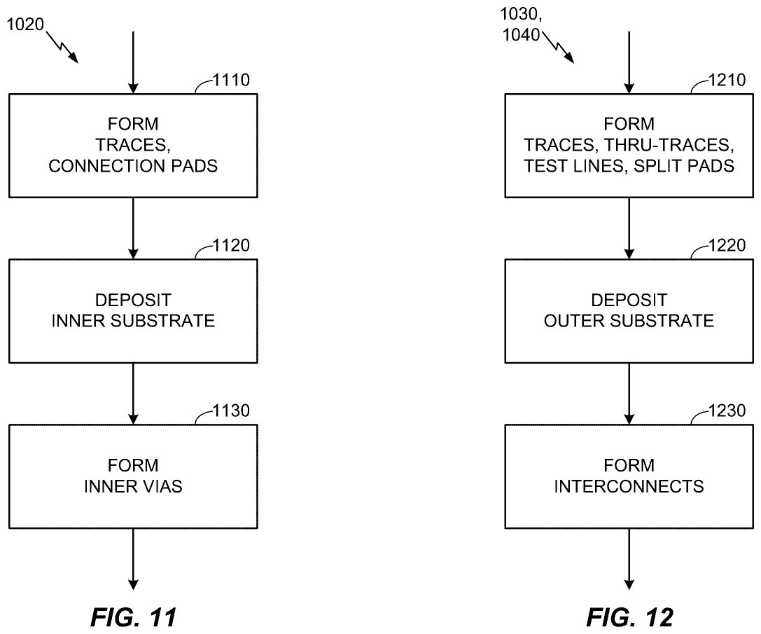

FIG. 11 illustrates a flow chart of an example process to perform block 1020. In block 1110, inner traces and inner connection pads may be formed. For example, as illustrated in FIG. 8C, the inner traces 342 and the inner connection pads 344 may be formed. In block 1120, a substrate material may be deposited to form the inner substrate. For example, as illustrated in FIG. 8B, the second inner substrate 355 may be formed. As another example illustrated in FIG. 8D, the inner substrate 345 may be formed. In block 1130, inner vias may be formed. For example, as illustrated in 8B and 8C, the second inner via holes 853 may be filled to form the second inner vias 353. Also as illustrated in FIGS. 8D and 8E, the inner via holes 843 may be filled with conductive materials (e.g., copper) to formed the inner vias 343.

Referring back to FIG. 10, in block 1030, the outer connection layer 320 may be formed. In block 1040, the interconnects 310 may be formed on the outer connection layer 320. FIG. 12 illustrates a flow chart of an example process to perform blocks 1030, 1040. In block 1210, traces 222, through-traces 225, and split pads 230, sense split pads (e.g., 250) and test lines (e.g., 255) may be formed (e.g., see FIG. 8E). In block 1220, a substrate material may be deposited to form the outer substrate 235 (e.g., see FIG. 8E). In block 1230, the interconnects 310 may be formed (e.g., see FIGS. 8F, 9A, 9B).

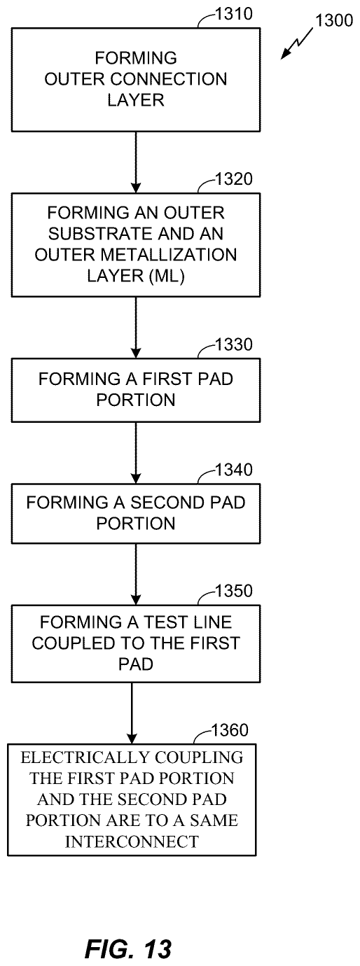

FIG. 13 illustrates a flowchart of a method for manufacturing a device in accordance with one or more aspects of the disclosure. The method 1300 for fabricating an apparatus (e.g., package board 300, package 700, etc.), as disclosed herein includes, at block 1310, forming an outer connection layer. Forming the outer layer comprises, at block 1320 forming an outer substrate and an outer metallization layer (ML). Forming the outer ML includes, forming a first set of split pads, which comprises, at block 1330, forming a first pad portion and at block 1340, a second pad portion; and at block 1350, forming a test line coupled to the first pad portion. At block 1360, the method continues with electrically coupling the first pad portion and the second pad portion to a same interconnect.

It should be noted that not all illustrated blocks of FIGS. 10, 11, 12 and 13 need be performed, i.e., some blocks may be optional. Also, the numerical references to the blocks in these figures should not be taken as requiring that the blocks should be performed in a certain order. Indeed, some blocks may be performed concurrently. Accordingly, it will be appreciated from the foregoing disclosure that additional processes for fabricating the various aspects disclosed herein will be apparent to those skilled in the art and a literal rendition of the processes discussed above will not be provided or illustrated in the included drawings. It will be appreciated that the sequences of the fabrication processes are not necessarily in any order and later processes may be discussed earlier to provide an example of the breadth of the various aspects disclosed.

The foregoing disclosed devices and functionalities may be designed and stored in computer files (e.g., register-transfer level (RTL), Geometric Data Stream (GDS) Gerber, and the like) stored on computer-readable media. Some or all such files may be provided to fabrication handlers who fabricate devices based on such files. Resulting products may include various components, including semiconductor wafers that are then cut into semiconductor die and packaged into semiconductor packages, integrated devices, package on package devices, system-on-chip devices and the like, which may then be employed in the various devices described herein.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

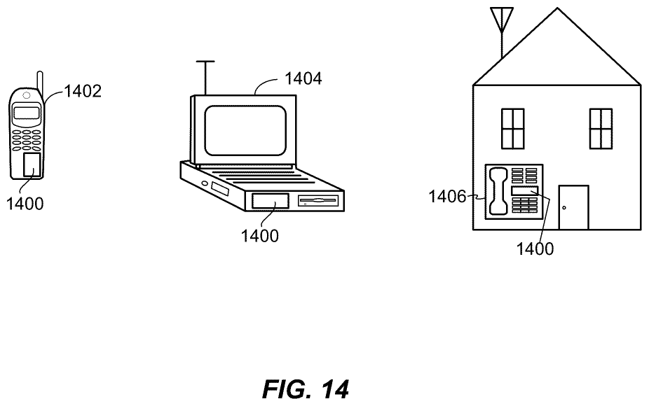

FIG. 14 illustrates various electronic devices that may be integrated with the aforementioned package board 300 and package 700. For example, a mobile phone device 1402, a laptop computer device 1404, a terminal device 1406 as well as wearable devices, portable systems, that require small form factor, extreme low profile, may include an apparatus 1400 that incorporates the object detection devices/systems as described herein. The apparatus 1400 may also be a standalone device, such as a video sensor. The devices 1402, 1404, 1406 illustrated in FIG. 14 are merely exemplary. Other electronic devices may also feature the apparatus 1400 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, Internet of Things (loT) devices, servers, routers, electronic devices implemented in automotive vehicles (e.g., autonomous vehicles), or any other device that stores or retrieves data or computer instructions, or any combination thereof.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An apparatus comprising an outer connection layer comprising: an outer substrate; and an outer metallization layer (ML), the outer ML includes a first set of sense split pads comprising: a first pad portion and a second pad portion; and a test line, wherein the test line is coupled to the first pad portion, and wherein the first pad portion and the second pad portion are electrically coupled to a same interconnect.

Clause 2. The apparatus of clause 1, wherein the second pad portion is electrically coupled to a power distribution network (PDN) through one or more PDN connections.

Clause 3. The apparatus of clause 2, wherein the one or more PDN connections are at least one or more vias, traces, shapes or planes.

Clause 4. The apparatus of any of clauses 1 to 3, wherein the test line is electrically coupled to a test point in the outer ML.

Clause 5. The apparatus of any of clauses 1 to 4, further comprising: one or more through-

traces, wherein at least one through-trace of the one or more through-traces vertically overlaps the same interconnect and is laterally disposed between the first pad portion and the second pad portion.

Clause 6. The apparatus of any of clauses 1 to 5, further comprising: an inner connection layer, wherein the outer connection layer is disposed on the inner connection layer; and one or more interconnects coupled to the outer connection layer opposite the inner connection layer.

Clause 7. The apparatus of clause 6, wherein the outer ML further comprises: a first set of split pads; and one or more through-traces, wherein first and second split pads of the first set of split pads are electrically coupled to a same interconnect of the one or more interconnects, and wherein at least one through-trace of the one or more through-traces vertically overlap the same interconnect and is disposed laterally between the first and second split pads.

Clause 8. The apparatus of clause 7, wherein the at least one through-trace is electrically separate from the first pad portion and the second pad portion.

Clause 9. The apparatus of clause 8, wherein the at least one through-trace is configured to carry a high-speed signal.

Clause 10. The apparatus of clause 9, wherein the at least one through-trace comprises first and second through-traces configured to carry a differential signal pair.

Clause 11. The apparatus of any of clauses 9 to 10, wherein the same interconnect and the first and second split pads are configured to be electrically coupled to ground.

Clause 12. The apparatus of any of clauses 7 to 11, wherein the outer ML further comprises: an inner substrate; an inner ML within the inner substrate and below a top surface of the inner connection layer, the inner ML comprising a plurality of inner connection pads; and a plurality of inner vias within the inner substrate and on the plurality of inner connection pads, each inner via being electrically coupled to its corresponding inner connection pad, and wherein first and second inner vias respectively are electrically coupled to the first and second split pads such that the first and second inner vias are electrically coupled to each other.

Clause 13. The apparatus of clause 12, wherein the first and second inner vias are electrically coupled to a same inner connection pad of the plurality of inner connection pads.

Clause 14. The apparatus of any of clauses 7 to 13, wherein the inner connection layer comprises: an inner substrate; an inner ML within the inner substrate and below a top surface of the inner connection layer, the inner ML comprising a plurality of inner connection pads; and a plurality of inner vias within the inner substrate and on the plurality of inner connection pads, each inner via being electrically coupled to its corresponding inner connection pad, and wherein one split pad of the first and second split pads is in physical contact with one inner via of the plurality of inner vias, and wherein an other split pad of the first and second split pads is not in physical contact with any of the plurality of inner vias.

Clause 15. The apparatus of clause 14, wherein the inner ML further comprises one or more inner traces, and wherein the other split pad vertically overlaps at least one inner trace of the one or more inner traces without being electrically coupled to the at least one inner trace.

Clause 16. The apparatus of any of clauses 1 to 15, wherein the test line has an opened portion.

Clause 17. The apparatus of any of clauses 1 to 16, wherein the test line has a width of 20 micrometers.

Clause 18. The apparatus of any of clauses 1 to 17, wherein at least one sense split pad further comprises at least one additional pad portion.

Clause 19. The apparatus of clause 18, wherein the at least one sense split pad further comprises at least one additional test line.

Clause 20. The apparatus of any of clauses 1 to 19, wherein the apparatus comprises at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of Things (IoT) device, a laptop computer, a server, an access point, a base station, or a device in an automotive vehicle.

Clause 21. A method for fabricating an apparatus comprising: forming an outer connection layer, wherein forming the outer connection layer comprises: forming an outer substrate; and forming an outer metallization layer (ML), wherein forming the outer ML comprises forming a first set of sense split pads, comprising: forming a first pad portion and a second pad portion; and forming a test line coupled to the first pad portion, and electrically coupling the first pad portion and the second pad portion to a same interconnect.

Clause 22. The method of clause 21, wherein the second pad portion is electrically coupled to a power distribution network (PDN) through one or more PDN connections.

Clause 23. The method of clause 22, wherein the one or more PDN connections are at least one or more vias, traces, shapes or planes.

Clause 24. The method of any of clauses 21 to 23, wherein the test line is electrically coupled to a test point in the outer ML.

Clause 25. The method of any of clauses 21 to 24, further comprising: forming one or more through-traces, wherein at least one through-trace of the one or more through-traces vertically overlaps the same interconnect and is laterally disposed between the first pad portion and the second pad portion.

Clause 26. The method of any of clauses 21 to 25, further comprising: forming an inner connection layer, wherein the outer connection layer is disposed on the inner connection layer; and forming one or more interconnects coupled to the outer connection layer opposite the inner connection layer.

Clause 27. The method of clause 26, wherein forming the outer ML further comprises: forming a first set of split pads; and forming one or more through-traces, wherein first and second split pads of the first set of split pads are electrically coupled to a same interconnect of the one or more interconnects, and wherein at least one through-trace of the one or more through-traces vertically overlap the same interconnect and is disposed laterally between the first and second split pads.

Clause 28. The method of any of clauses 21 to 27, further comprising: forming an opened portion in the test line.

Clause 29. The method of any of clauses 26 to 28, wherein the test line has a width of 20 micrometers.

Clause 30. The method of any of clauses 26 to 29, wherein the apparatus comprises at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of Things (IoT) device, a laptop computer, a server, an access point, a base station, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An apparatus comprising an outer connection layer comprising:
an outer substrate; and
an outer metallization layer (ML), the outer ML includes a first set of sense split pads comprising:
a first pad portion and a second pad portion; and
a test line,
wherein the test line is coupled to the first pad portion, and
wherein the first pad portion and the second pad portion are electrically coupled to a same interconnect.

2. The apparatus of claim 1, wherein the second pad portion is electrically coupled to a power distribution network (PDN) through one or more PDN connections.

3. The apparatus of claim 2, wherein the one or more PDN connections are at least one or more vias, traces, shapes or planes.

4. The apparatus of claim 1, wherein the test line is electrically coupled to a test point in the outer ML.

5. The apparatus of claim 1, further comprising:
one or more through-traces, wherein at least one through-trace of the one or more through-traces vertically overlaps the same interconnect and is laterally disposed between the first pad portion and the second pad portion.

6. The apparatus of claim 1, further comprising:
an inner connection layer, wherein the outer connection layer is disposed on the inner connection layer; and
one or more interconnects coupled to the outer connection layer opposite the inner connection layer.

7. The apparatus of claim 6, wherein the outer ML further comprises:
a first set of split pads; and
one or more through-traces,
wherein first and second split pads of the first set of split pads are electrically coupled to a same interconnect of the one or more interconnects, and
wherein at least one through-trace of the one or more through-traces vertically overlap the same interconnect and is disposed laterally between the first and second split pads.

8. The apparatus of claim 7, wherein the at least one through-trace is electrically separate from the first pad portion and the second pad portion.

9. The apparatus of claim 8, wherein the at least one through-trace is configured to carry a high-speed signal.

10. The apparatus of claim 9, wherein the at least one through-trace comprises first and second through-traces configured to carry a differential signal pair.

11. The apparatus of claim 9, wherein the same interconnect and the first and second split pads are configured to be electrically coupled to ground.

12. The apparatus of claim 7, wherein the outer ML further comprises:
an inner substrate;
an inner ML within the inner substrate and below a top surface of the inner connection layer, the inner ML comprising a plurality of inner connection pads; and
a plurality of inner vias within the inner substrate and on the plurality of inner connection pads, each inner via being electrically coupled to its corresponding inner connection pad, and
wherein first and second inner vias respectively are electrically coupled to the first and second split pads such that the first and second inner vias are electrically coupled to each other.

13. The apparatus of claim 12, wherein the first and second inner vias are electrically coupled to a same inner connection pad of the plurality of inner connection pads.

14. The apparatus of claim 7, wherein the inner connection layer comprises:
an inner substrate;
an inner ML within the inner substrate and below a top surface of the inner connection layer, the inner ML comprising a plurality of inner connection pads; and
a plurality of inner vias within the inner substrate and on the plurality of inner connection pads, each inner via being electrically coupled to its corresponding inner connection pad, and
wherein one split pad of the first and second split pads is in physical contact with one inner via of the plurality of inner vias, and
wherein an other split pad of the first and second split pads is not in physical contact with any of the plurality of inner vias.

15. The apparatus of claim 14, wherein the inner ML further comprises one or more inner traces, and wherein the other split pad vertically overlaps at least one inner trace of the one or more inner traces without being electrically coupled to the at least one inner trace.

16. The apparatus of claim 1, wherein the test line has an opened portion.

17. The apparatus of claim 1, wherein the test line has a width of 20 micrometers.

18. The apparatus of claim 1, wherein at least one sense split pad further comprises at least one additional pad portion.

19. The apparatus of claim 18, wherein the at least one sense split pad further comprises at least one additional test line.

20. The apparatus of claim 1, wherein the apparatus comprises at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of Things (IoT) device, a laptop computer, a server, an access point, a base station, or a device in an automotive vehicle.

21. A method for fabricating an apparatus comprising:
forming an outer connection layer, wherein forming the outer connection layer comprises:
forming an outer substrate; and
forming an outer metallization layer (ML), wherein forming the outer ML comprises forming a first set of sense split pads, comprising:
forming a first pad portion and a second pad portion; and
forming a test line coupled to the first pad portion, and
electrically coupling the first pad portion and the second pad portion to a same interconnect.

22. The method of claim 21, wherein the second pad portion is electrically coupled to a power distribution network (PDN) through one or more PDN connections.

23. The method of claim 22, wherein the one or more PDN connections are at least one or more vias, traces, shapes or planes.

24. The method of claim 21, wherein the test line is electrically coupled to a test point in the outer ML.

25. The method of claim 21, further comprising:
forming one or more through-traces, wherein at least one through-trace of the one or more through-traces vertically overlaps the same interconnect and is laterally disposed between the first pad portion and the second pad portion.

26. The method of claim 21, further comprising:
forming an inner connection layer, wherein the outer connection layer is disposed on the inner connection layer; and
forming one or more interconnects coupled to the outer connection layer opposite the inner connection layer.

27. The method of claim 26, wherein forming the outer ML further comprises:
forming a first set of split pads; and
forming one or more through-traces,
wherein first and second split pads of the first set of split pads are electrically coupled to a same interconnect of the one or more interconnects, and
wherein at least one through-trace of the one or more through-traces vertically overlap the same interconnect and is disposed laterally between the first and second split pads.

28. The method of claim 21, further comprising: forming an opened portion in the test line.

29. The method of claim 26, wherein the test line has a width of 20 micrometers.

30. The method of claim 26, wherein the apparatus comprises at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of Things (IoT) device, a laptop computer, a server, an access point, a base station, or a device in an automotive vehicle.
